(19) United States
(12) Patent Application Publication
(10) Pub. No.: US 2025/0285825 A1
(43) Pub. Date: Sep. 11, 2025

(54) ELECTROSTATIC ENERGY FILTER MODULE

(71) Applicant: Applied Materials Israel Ltd., Rehovot (IL)

(72) Inventors: Itamar Luzon, Rehovot (IL); Eyal Nahum, Rehovot (IL)

(73) Assignee: Applied Materials Israel Ltd., Rehovot (IL)

(21) Appl. No.: 18/599,138

(22) Filed: Mar. 7, 2024

(51) Int. Cl. H01J 3/28

(52) U.S. Cl. CPC H01J 3/28

(57) ABSTRACT

An electrostatic energy filter module that includes a (i) biasing circuit, (ii) distal electrodes, (iii) intermediate electrodes that are upstream to the distal electrodes; and (iv) proximal electrodes that are upstream to the intermediate electrodes. The electrodes are disk-shaped, concentric, are parallel to each other and define an optical axis. The distal electrodes are configured to receive first biasing signals from the biasing circuit, and to form first equipotential lines that are parallel to each other and are perpendicular to the optical axis. The intermediate electrodes are configured to receive second biasing signals from the biasing circuit, and to form a wide energy barrier. The proximal electrodes are configured to third biasing signals from the biasing circuit, and to form second equipotential lines that are parallel to each other and are perpendicular to the optical axis.

### BACKGROUND OF THE INVENTION

Evaluation systems include inspection systems, review systems and metrology systems. An evaluation system uses a charged particle beam to illuminate a sample and is also configured to collect emitted charged particles resulting from the illumination of the sample, and to selectively detect the emitted charged particles.

The selective detection is implemented by using an electrostatic energy filter located upstream to a detector. The electrostatic energy filter prevents charged particles of certain energies to reach the detector while allowing charged particles of other energies to pass through the electrostatic energy filter.

There is a growing need to provide an electrostatic energy filter module with few distortions and high collection efficiency.

### BRIEF SUMMARY OF THE INVENTION

There is provided an electrostatic energy filter module.

According to an embodiment, there is provided an electrostatic energy filter module that includes (i) a biasing circuit; and (ii) multiple electrodes. The multiple electrodes comprise (a) distal electrodes, (b) intermediate electrodes that are upstream to the distal electrodes, and (c) proximal electrodes that are upstream to the intermediate electrodes. The multiple electrodes are disk-shaped, concentric, are parallel to each other and define an optical axis. The optical axis passes through the centers of the multiple electrodes.

The distal electrodes are configured to receive the first biasing signals from the biasing circuit, and to form first equipotential lines that are parallel to each other and are perpendicular to the optical axis. The intermediate electrodes are configured to receive second biasing signals from the biasing circuit, and to form a wide energy barrier. The proximal electrodes are configured to third biasing signals from the biasing circuit, and to form second equipotential lines that are parallel to each other and

According to an embodiment, there is provided a method for energy filtering, the method includes (i) biasing multiple electrodes of an electrostatic energy filter module, by a biasing circuit of the electrostatic energy filter module, and (ii) forming electrostatic fields.

The biasing includes sending first biasing signals to distal electrodes of the multiple electrodes, sending second biasing signals to intermediate electrodes of the multiple electrodes, and sending third biasing signals to proximal electrodes of the multiple electrodes.

The forming of the electrostatic fields includes (i) forming, by the distal electrodes, first equipotential lines that are parallel to each other and are perpendicular to an optical axis defined by the multiple electrodes; (ii) forming, by the intermediate electrodes, a wide energy barrier; and (iii) forming, by the proximal electrodes, second equipotential lines that are parallel to each other and are perpendicular to the optical axis.

According to an embodiment, the method further includes receiving an electron beam by the electrostatic energy filter module and filtering the electron beam to provide a filtered electron beam.

### BRIEF DESCRIPTION OF THE DRAWINGS

The subject matter regarded as the embodiment is particularly pointed out and distinctly claimed in the concluding portion of the specification. The embodiment, however, both as to organization and method of operation, together with specimen s, features, and advantages thereof, may best be understood by reference to the following detailed description when read with the accompanying drawings in which:

FIG. 1 illustrates an example of an electrostatic energy filter module;

FIG. 2 illustrates an example of an electrostatic energy filter module;

FIG. 3 illustrates an example of an electrostatic energy filter module;

FIG. 4 illustrates an example of electric potentials;

FIG. 5 illustrates an example of electric potentials;

FIG. 6 illustrates an example of an electrostatic energy filter module; and

FIG. 7 illustrates an example of a method according to embodiments disclosed herein.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

There is provided an electrostatic energy filter module that is compact, and includes multiple electrodes that are disk-shaped, concentric, are parallel to each other and define an optical axis.

According to an embodiment, the electrostatic energy filter module is configured to form an energy barrier that is wide. Examples of wide include: above 0.49 mm, between 0.5 mm to 3.5 mm, between 3.51 mm to 6 mm, between 6.01 mm to 8 mm, between 8.01 mm and 12 mm, and the like.

The energy barrier reduces distortion as it applies the same filtering operation regardless of the location of the electron beam within the energy barrier.

The energy filter may be set to filter secondary electrons or, additionally or alternatively, backscattered electrons.

According to an embodiment, the energy barrier is formed within an empty inner space surrounded by electrodes. Thereby the electron beam does not pass through absorbing elements such as grid wires thereby reducing the losses associated with energy grid filtering.

According to an embodiment, the energy barrier is formed within a filtering region that is preceded by a deceleration region and is followed by an acceleration region.

According to an embodiment, the electrostatic energy filter module reduces distortion to the electron beam within the deceleration region by applying first equipotential lines that are parallel to each other and are perpendicular to the optical axis.

According to an embodiment that equipotential lines are substantially parallel to each other and are substantially perpendicular to the optical axis. The term “substantially” refers to a deviation of up to 1, 2, 3, 4, 5, 6, 7, 8, 9, 10 degrees and the like.

According to an embodiment, the electrostatic energy filter module reduces distortion to the electron beam within the acceleration region by applying second equipotential lines that are parallel to each other and are perpendicular to the optical axis.

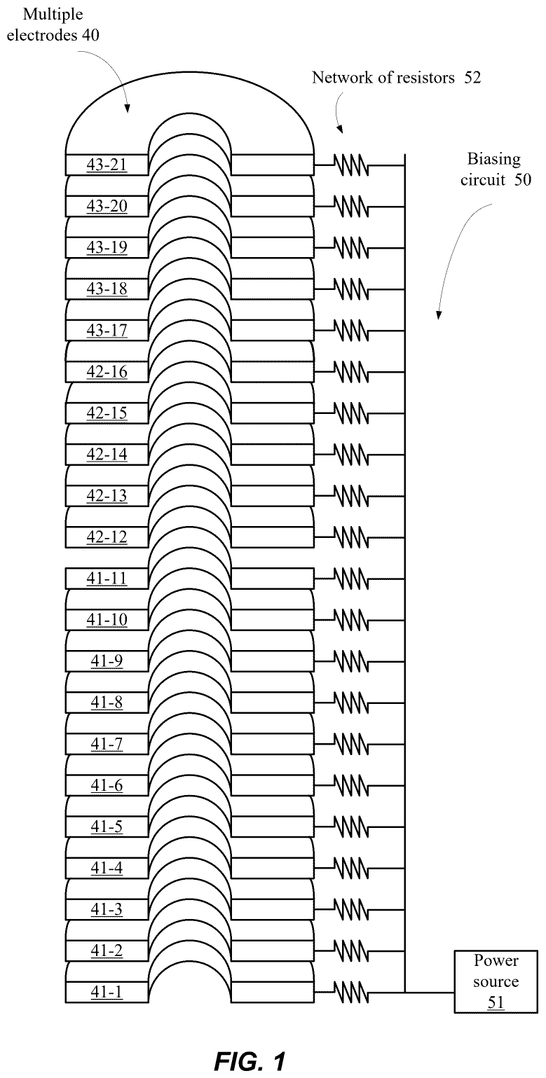

According to an embodiment, and referring to FIG. 1, the electrostatic energy filter module includes a biasing circuit 50. The biasing circuit includes power source 51 and a network of resistors 52. The electrostatic energy filter module further includes multiple electrodes 40).

The multiple electrodes include:
a. Distal electrodes 41-1 till 41-11 that are located within a deceleration region.
b. Intermediate electrodes 42-12 till 42-16 that are located within the filtering region and are upstream to the distal electrodes.
c. Proximal electrodes 43-17 till 43-21 that are located within an acceleration region upstream to the intermediate electrodes.

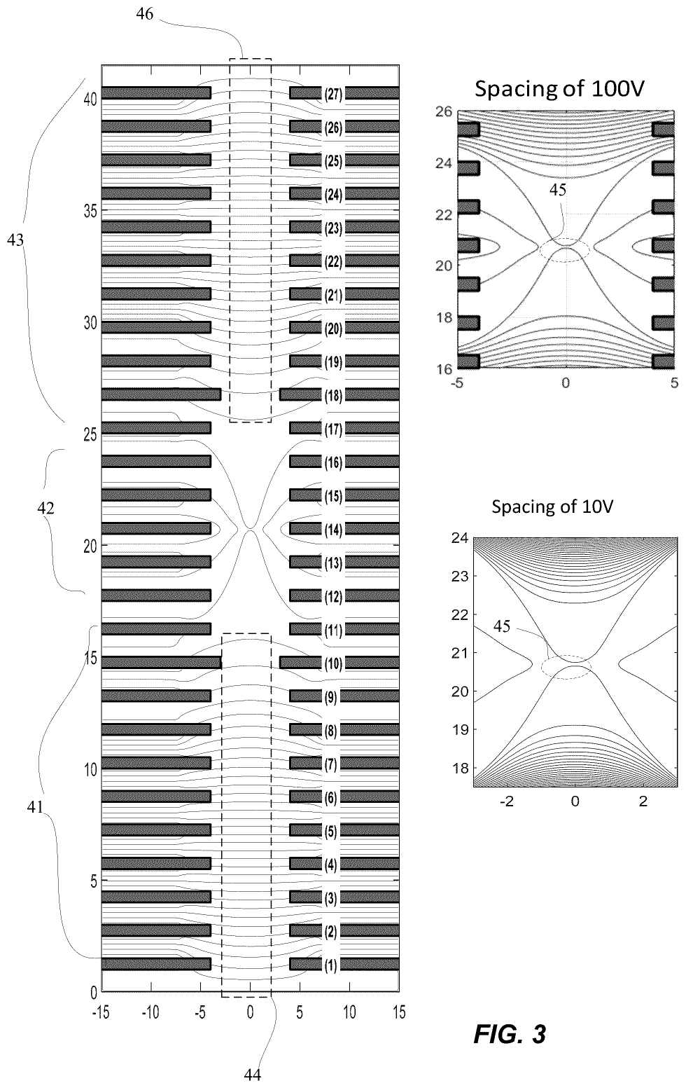

According to an embodiment, the distal electrodes are configured to receive first biasing signals from the biasing circuit, and to form first equipotential lines (denoted 44 in FIG. 3) that are parallel to each other and are perpendicular to the optical axis.

According to an embodiment, the intermediate electrodes are configured to receive second biasing signals from the biasing circuit, and to form an energy barrier (denoted 45 in FIG. 3).

According to an embodiment, the proximal electrodes are configured to receive third biasing signals from the biasing circuit, and to form second equipotential lines (denoted 46 in FIG. 3) that are parallel to each other and are perpendicular to the optical axis.

According to an embodiment, the multiple electrodes include between twenty and forty electrodes. The number of electrodes may be lower than twenty or exceed forty.

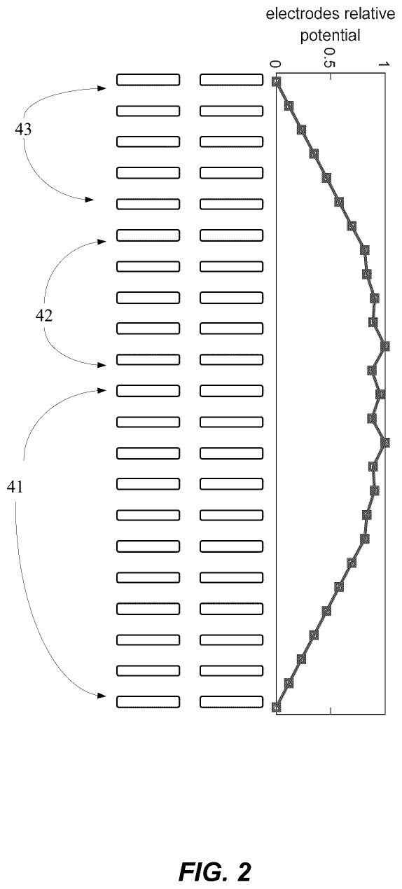

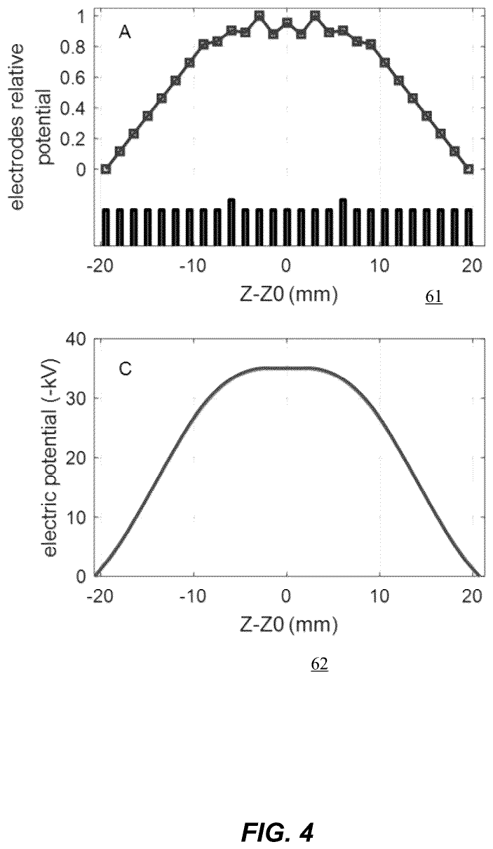

According to an embodiment, wherein at least a majority of the first bias signals introduce a gradually increasing potential, wherein at least a majority of second first bias signals introduce an even potential, and wherein at least a majority of the third bias signals introduce a gradually decreasing potential. An example of such biasing signals is illustrated in FIG. 2. See also, plot 61 of FIG. 4.

FIG. 1 illustrates a biasing circuit that includes a single voltage source and a network of resistors.

According to an embodiment, other biasing circuits may be provided, for example, a biasing circuit that includes voltage sources and networks of resistors.

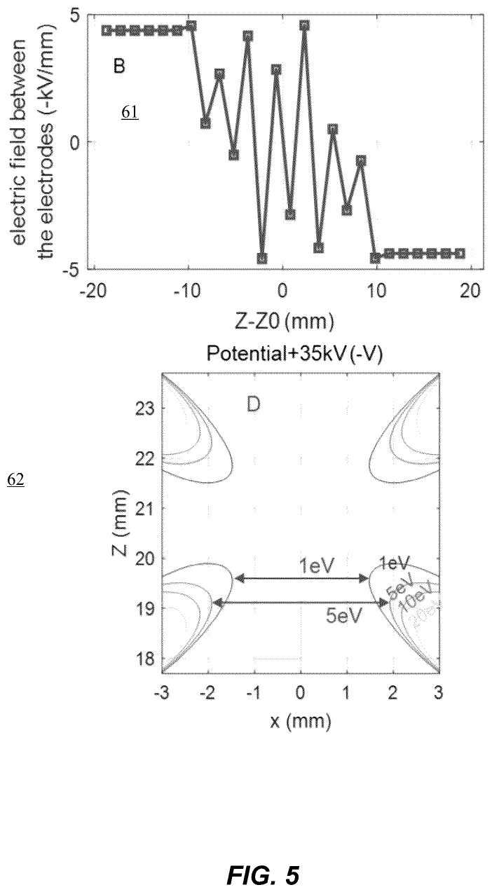

FIGS. 4 and 5 include plots 61, 62, 63 and 64 that show potentials along Z axis (optical axis) for potential barrier of 35 keV by setting the power supply on −37.9 kV. Plot 61 shows the electrodes positions and their relative optimized potentials, where the distal electrodes are used to decelerate the electron beam and the intermediate electrodes are used to obtain the energy barrier.

Plot 62 showed the resulted field between the electrodes with a maximal field of 4.6 kV/mm lower than 5 kV/mm to minimize risk for arcing. The plot is the same for different distances from the optical axis, the distances include 0.1 mm, 1 mm, 2 mm and 3 mm from the optical axis.

Plot 63 illustrates the substantial potential along the electrostatic energy filter module in different radius from the optical axis. This shows the same potential for a large-scale point of view.

Plot 64 shown is a zoomed view of the energy barrier area potentials. This plot shows 4 mm and 3 mm waist barrier with 6 eV and 1 eV energetic resolution respectively for a 35 keV electron beam.

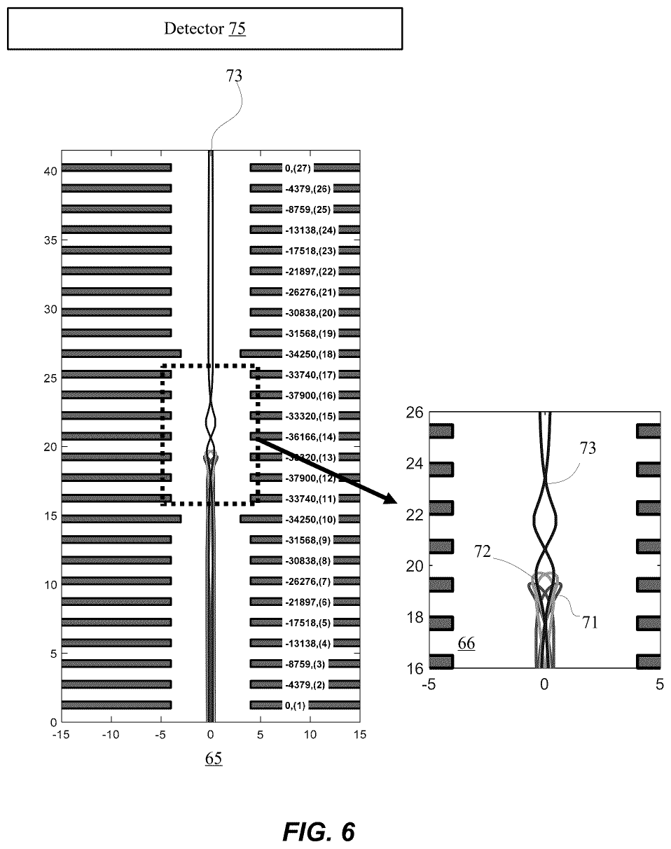

FIG. 6 illustrates an example of an electrostatic energy filter module that applies a filtering operation by applying a potential barrier of 35 keV as a filtering resolution of lev. Electrons 71 that had an energy of 35001 ev passed the energy barrier. Electrons 72 that had an energy of 35000 ev failed to pass the energy barrier. Electrons 73 that had an energy of 34999 ev failed to pass the energy barrier. FIG. 5 also illustrates a detector 75 located downstream to the electrostatic energy filter module. The detector may be configured to detect electrons 71.

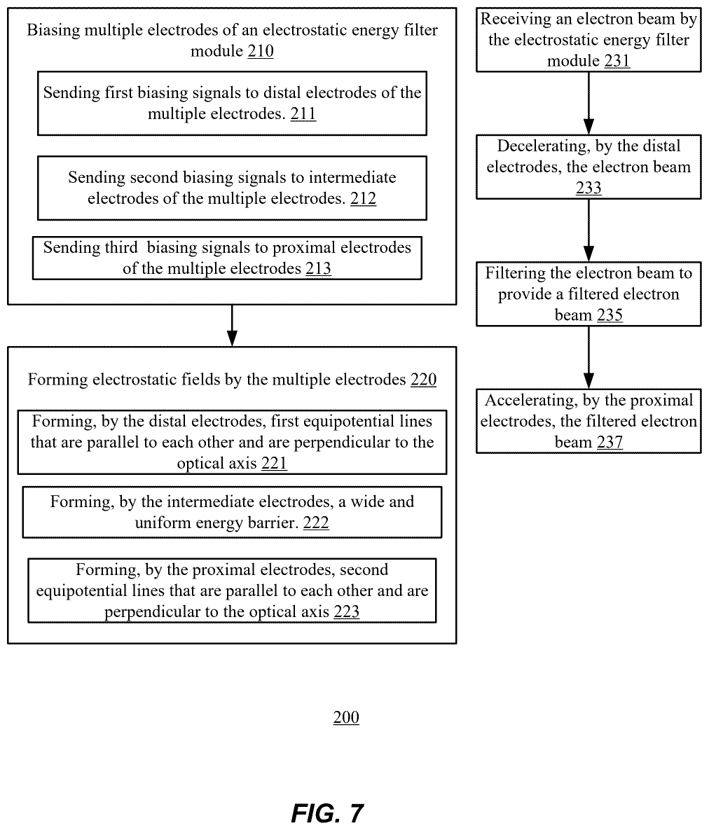

FIG. 7 illustrates an example of a method 200 for energy filtering.

According to an embodiment, method 200 includes step 210 of biasing multiple electrodes of an electrostatic energy filter module, by a biasing circuit of the electrostatic energy filter module.

According to an embodiment, step 210 includes:
a. Introducing, by at least a majority of the first bias signals, a gradually increasing potential.
b. Introducing, by at least a majority of second first bias signals an even potential.
c. Introducing, by at least a majority of the third bias signals, a gradually decreasing potential.

According to an embodiment, step 210 includes:
a. Step 211 of sending first biasing signals to distal electrodes of the multiple electrodes.
b. Step 212 of sending second biasing signals to intermediate electrodes of the multiple electrodes.
c. Step 213 of sending third biasing signals to proximal electrodes of the multiple electrodes.

According to an embodiment, method 200 also include step 220 of forming electrostatic fields by the multiple electrodes.

According to an embodiment, step 220 includes:
a. Step 221 of forming, by the distal electrodes, first equipotential lines that are parallel to each other and are perpendicular to the optical axis.
b. Step 222 of forming, by the intermediate electrodes, an energy barrier.
c. Step 223 of forming, by the proximal electrodes, second equipotential lines that are parallel to each other and are perpendicular to the optical axis.

According to an embodiment, method 200 further includes sequence of steps. The sequence of steps occur during the execution of steps 210 and 220.

The sequence of steps includes:
a. Step 231 of receiving an electron beam by the electrostatic energy filter module.
b. Step 233 of decelerating, by the distal electrodes, the electron beam.
c. Step 235 of filtering the electron beam to provide a filtered electron beam.
d. Step 237 of accelerating, by the proximal electrodes, the filtered electron beam.

According to an embodiment, the electron beam exhibits a width expansion rate that corresponds to an initial angular width of the electron beam when reaching the electrostatic energy filter module. According to an embodiment, the distal electrodes have an overall length (span along) a short distance. According to an embodiment, the short distance is measured along the optical axis and may be, for example, less than 5 cm. The short overall length reduces (in comparison to a longer electrostatic energy filter module) the width expansion of the electron beam.

In the foregoing detailed description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using electronic components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure.

Any reference in the specification to a method should be applied mutatis mutandis to a system capable of executing the method.

Any reference in the specification to a system should be applied mutatis mutandis to a method that may be executed by the system.

The term “and/or” means additionally or alternatively. For example, A and/or B means only A, or only B or A and B.

In the foregoing description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the foregoing specification, the embodiments of the disclosure have been described with reference to specific examples of embodiments. It will, however, be evident that various modifications and changes may be made therein without departing from the broader spirit and scope of the appended claims.

Moreover, the terms “front,” “back,” “top,”, “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Any reference to the term “comprising” or “having” or “including” should be applied mutatis mutandis to “consisting of” and/or should be applied mutatis mutandis to “consisting essentially of”.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to embodiments containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments have been illustrated and described herein, many modifications, substitutions, changes, and equivalents will now occur to those of ordinary skill in the art. It is, therefore, to be understood that the appended claims are intended to cover all such modifications and changes as fall within the true spirit of the embodiment.

What is claimed is:

1. An electrostatic energy filter module comprising:
a biasing circuit; and
multiple electrodes including distal electrodes, intermediate electrodes that are upstream to the distal electrodes, and proximal electrodes that are upstream to the intermediate electrodes;
wherein the multiple electrodes are disk-shaped, concentric, parallel to each other and define an optical axis;
wherein the distal electrodes are configured to receive first biasing signals from the biasing circuit, and to form first equipotential lines that are parallel to each other and perpendicular to the optical axis;
wherein the intermediate electrodes are configured to receive second biasing signals from the biasing circuit, and to form a wide energy barrier; and
wherein the proximal electrodes are configured to receive third biasing signals from the biasing circuit, and to form second equipotential lines that are parallel to each other and are perpendicular to the optical axis.

2. The electrostatic energy filter module according to claim 1, wherein the distal electrodes are further configured to decelerate an electron beam, the intermediate electrodes are configured to filter the electron beam to provide a filtered electron beam and the proximal electrodes are configured to accelerate the filtered electron beam.

3. The electrostatic energy filter module according to claim 2, wherein an overall length of the distal electrodes does not exceed 5 cm.

4. The electrostatic energy filter module according to claim 1, wherein the multiple electrodes include between twenty and forty electrodes.

5. The electrostatic energy filter module according to claim 1, wherein at least a majority of the first bias signals introduce a gradually increasing potential, wherein at least a majority of second first bias signals introduce an even potential, and wherein at least a majority of the third bias signals introduce a gradually decreasing potential.

6. The electrostatic energy filter module according to claim 1, wherein the biasing circuit comprises a single voltage source and a network of resistors.

7. The electrostatic energy filter module according to claim 1, wherein the biasing circuit comprises voltage sources and networks of resistors.

8. A method for energy filtering, the method comprising:
biasing multiple electrodes of an electrostatic energy filter module, by a biasing circuit of the electrostatic energy filter module, wherein the biasing comprises: sending first biasing signals to distal electrodes of the multiple electrodes, sending second biasing signals to intermediate electrodes of the multiple electrodes, and sending third biasing signals to proximal electrodes of the multiple electrodes;
forming, by the distal electrodes, first equipotential lines that are parallel to each other and are perpendicular to an optical axis defined by the multiple electrodes;
forming, by the intermediate electrodes, a wide energy barrier;
forming, by the proximal electrodes, second equipotential lines that are parallel to each other and are perpendicular to the optical axis;
receiving an electron beam by the electrostatic energy filter module; and
filtering the electron beam to provide a filtered electron beam.

9. The method according to claim 8, further comprising:
decelerating, by the distal electrodes, the electron beam;
filtering, by the intermediate electrodes, the electron beam to provide a filtered electron beam; and
accelerating, by the proximal electrodes, the filtered electron beam.

10. The method according to claim 8, wherein the electron beam exhibits a width expansion rate that corresponds to an initial angular width of the electron beam when reaching the electrostatic energy filter module, wherein an overall length of the distal electrodes does not exceed 5 cm.

11. The method according to claim 8, wherein the multiple electrodes include between twenty and forty electrodes.

12. The method according to claim 8, wherein the biasing comprises:
introducing, by at least a majority of the first bias signals, a gradually increasing potential;
introducing, by at least a majority of second first bias signals an even potential; and
introducing, by at least a majority of the third bias signals, a gradually decreasing potential.

13. The method according to claim 8, wherein the biasing circuit comprises a single voltage source and a network of resistors.

14. The method according to claim 8, wherein the biasing circuit comprises voltage sources and networks of resistors.
